(19) United States
(12) Patent Application Publication
(10) Pub. No.: US 2026/0164936 A1
(43) Pub. Date: Jun. 11, 2026

(54) THIN FILM TRANSISTOR SUBSTRATE AND DISPLAY APPARATUS COMPRISING THE SAME

(71) Applicant: LG Display Co., Ltd., Seoul (KR)

(72) Inventors: HeeJun Kim, Paju-si (KR); YounGyoung Chang, Paju-si (KR); Jiyong Noh, Paju-si (KR); ChanYong Jeong, Paju-si (KR)

(73) Assignee: LG Display Co., Ltd., Seoul (KR)

(21) Appl. No.: 19/352,276

(22) Filed: Oct. 7, 2025

(30) Foreign Application Priority Data
Dec. 6, 2024 (KR) 10-2024-0180322

(51) Int. Cl. H10K 59/121; G09G 3/3233; G09G 3/3266; H10K 59/131

(52) U.S. Cl. CPC H10K 59/1213; G09G 3/3233; G09G 3/3266; H10K 59/131; G09G 2300/0842; G09G 2310/0286; G09G 2320/043

(57) ABSTRACT

A thin film transistor substrate includes a base substrate, and first and second thin film transistors on the base substrate and connected to each other in series. The first thin film transistor includes a first active layer having a first channel portion, a first gate electrode insulated from the first active layer and overlapping the first active layer, and first source and first drain electrodes in contact with the first active layer and spaced apart from each other. The second thin film transistor includes a second active layer having a second channel portion, a second gate electrode insulated from the second active layer and overlapping the second active layer, and second source and second drain electrodes in contact with the second active layer and spaced apart from each other. The first drain electrode and the second source electrode may be formed integrally and disposed on a same underlying layer.

### CROSS-REFERENCE TO RELATED APPLICATION

This application claims the benefit of priority of Korean Patent Application No. 10-2024-0180322, filed on Dec. 6, 2024, which is hereby incorporated by reference as if fully set forth herein.

### BACKGROUND

### Field of the Disclosure

The present disclosure relates to a thin film transistor substrate and a display apparatus including the same.

### Discussion of the Related Art

Since thin film transistors can be manufactured on glass or plastic substrates, they are widely used as switching elements or driving elements in display apparatuses, such as liquid crystal display apparatuses or organic light emitting devices.

Based on the material constituting the active layer, thin film transistors can be classified into amorphous silicon thin film transistors in which amorphous silicon is used as the active layer, polycrystalline silicon thin film transistors in which polycrystalline silicon is used as the active layer, and oxide semiconductor thin film transistors in which an oxide semiconductor is used as the active layer.

Thin film transistors may deteriorate as the operating time increases. When the thin film transistor deteriorates, the reliability of the thin film transistor element may deteriorate. When the reliability of the element deteriorates due to the deterioration of the thin film transistor, the image quality of the display apparatus may also deteriorate.

Research is being conducted continuously to prevent or suppress the deterioration of thin film transistors.

### SUMMARY

Accordingly, the present disclosure is directed to a thin film transistor substrate and a display apparatus including the same that substantially obviate ones or more problems due to limitations and disadvantages of the related art.

One or more embodiments of the present disclosure can provide a thin film transistor substrate in which stress applied due to high drain bias is reduced by forming a wide channel area of a thin film transistor to which a high potential voltage is applied.

One or more embodiments of the present disclosure can provide a thin film transistor substrate in which stress applied due to high drain bias is reduced by allowing a drain electrode of a thin film transistor to which a high potential voltage is applied to have a larger planar area than a source electrode in a plane.

One or more embodiments of the present disclosure can provide a thin film transistor substrate having a narrow bezel implemented by integrating a drain electrode and a source electrode of two different thin film transistors into a shared circular, oval, or elliptical structure.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, a thin film transistor substrate according one or more embodiments of the present disclosure includes a base substrate, and a first thin film transistor and a second thin film transistor on the base substrate and connected to each other in series. The first thin film transistor includes: a first active layer having a first channel portion; a first gate electrode insulated from the first active layer and overlapping the first active layer; and a first source electrode and a first drain electrode in contact with the first active layer and spaced apart from each other. The second thin film transistor includes: a second active layer having a second channel portion; a second gate electrode insulated from the second active layer and overlapping the second active layer; and a second source electrode and a second drain electrode in contact with the second active layer and spaced apart from each other. The first drain electrode and the second source electrode may be formed integrally and disposed on a same underlying layer.

In some embodiments, the integrally formed first drain electrode and second source electrode together may have a circular, rounded, oval, or elliptical shape in a plan view.

In some embodiments, the first gate electrode and the second gate electrode may integrally form a closed loop shape in a plan view, and the first drain electrode and the second source electrode may be disposed inside of the closed loop shape integrally formed by the first gate electrode and the second gate electrode in the plan view.

In some embodiments, the first active layer may further include a first source conductor portion disposed at one side of the first channel portion and a first drain conductor portion disposed at the other side of the first channel portion. The second active layer may further include a second source conductor portion disposed at one side of the second channel portion and a second drain conductor portion disposed at the other side of the second channel portion. The first channel portion and the second channel portion may be separated from each other by an opening portion therebetween.

In some embodiments, the first channel portion may have a first length and may have a first width perpendicular to the first length and extending along the first channel portion. The second channel portion may have a second length and may have a second width perpendicular to the second length and extending along the second channel portion. The second width may be longer than the first width. The first length and the second length may be equal.

In some embodiments, the second channel portion may have a larger planar area than the first channel portion in a plan view.

In some embodiments, the second drain electrode may have a larger planar area than the first source electrode in a plan view, and the first source electrode may have a larger planar area than the first drain electrode in the plan view.

In some embodiments, the first channel portion may have a U shape in a plan view, and the second channel portion may have an inverted U shape in the plan view. The first gate electrode may have a U shape in the plan view, and the second gate electrode may have an inverted U shape in the plan view.

In some embodiments, the first source electrode may have a U shape in a plan view, and the second drain electrode may have an inverted U shape in the plan view.

In some embodiments, the first gate electrode and the second gate electrode may integrally form any one of a circular ring, an elliptical ring, and a rectangular ring with rounded corners in a plan view. Each of an inner surface of the first source electrode and an inner surface of the second drain electrode may have a round or curved shape in the plan view.

In some embodiments, the first source electrode, the first drain electrode, the second source electrode, and the second drain electrode may be disposed on the same underlying layer, that is different from a layer on which the first gate electrode and the second gate electrode are disposed. The first active layer may be disposed between the base substrate and the first gate electrode, and the second active layer may be disposed between the base substrate and the second gate electrode.

In some embodiments, the first thin film transistor may further include a first light-blocking layer electrically connected to the first gate electrode and disposed between the base substrate and the first active layer. The second thin film transistor may further include a second light-blocking layer electrically connected to the second gate electrode and disposed between the base substrate and the second active layer. The first light-blocking layer may overlap the first gate electrode, and the second light-blocking layer may overlap the second gate electrode.

In some embodiments, the first gate electrode may be disposed between the base substrate and the first active layer, and the second gate electrode may be disposed between the base substrate and the second active layer.

In another aspect of the present disclosure, a display apparatus according to one or more embodiments includes a thin film transistor in accordance with any of the above example embodiments.

In some embodiments, the display apparatus may further include: a plurality of pixels each having a pixel driving circuit; a plurality of gate lines connected respectively to the plurality of pixels; and a gate driver having a plurality of stages each configured to drive a corresponding one of the plurality of gate lines and the pixel driving circuit of the corresponding one of the plurality of pixels. Each of the plurality of stages may include: an output circuit including a pull-up transistor configured to be pulled up by control of a Q node and to output a first clock signal input through a first clock terminal as an output to an output terminal, and including a pull-down transistor configured to pull down the output terminal by control of a QB node; and a control circuit configured to charge and discharges the Q node and to charge and discharge the QB node opposite to the Q node. The control circuit may include QB charging transistors configured to charge the QB node with a high potential voltage. The QB charging transistors include a first QB charging transistor and a second QB charging transistor. A drain electrode of the first QB charging transistor may be configured to receive the high potential voltage, and a source electrode of the second QB charging transistor may be connected to the QB node. The first QB charging transistor may be the second thin film transistor, and the second QB charging transistor may be the first thin film transistor.

In some embodiments, the control circuit may further include Q discharge transistors configured to discharge the Q node to a gate-off voltage by control of the QB node. The Q discharge transistors may include a third thin film transistor and a fourth thin film transistor connected in series with each other. The third thin film transistor may include: a third active layer having a third channel portion; a third gate electrode insulated from the third active layer and overlapping the third active layer; and a third source electrode and a third drain electrode in contact with the third active layer and spaced apart from each other. The fourth thin film transistor may include: a fourth active layer having a fourth channel portion; a fourth gate electrode insulated from the fourth active layer and overlapping the fourth active layer; and a fourth source electrode and a fourth drain electrode in contact with the fourth active layer and spaced apart from each other. The third gate electrode and the fourth gate electrode may be formed integrally and may be disposed on the same underlying layer. The third drain electrode and the fourth source electrode may be formed integrally, and a planar area of the third channel portion may be equal to a planar area of the fourth channel portion in a plan view.

In yet another aspect of the present disclosure, a thin film transistor substrate according to one or more embodiments of the present disclosure may include a base substrate, and a first thin film transistor and a second thin film transistor on the base substrate and connected to each other in series. The first thin film transistor and the second thin film transistor may share an integrated gate electrode having a closed loop shape in a plan view, the integrated gate electrode including a first gate electrode at one portion of the closed loop shape and a second gate electrode at another portion of the closed loop shape. The first thin film transistor may include: a first active layer having a first channel portion; the first gate electrode insulated from the first channel portion and overlapping the first channel portion; and a first source electrode and a first drain electrode in contact with the first active layer and disposed respectively at opposite sides of the first channel portion. The second thin film transistor may include: a second active layer having a second channel portion; the second gate electrode insulated from the second channel portion and overlapping the second channel portion; and a second source electrode and a second drain electrode in contact with the second active layer and disposed respectively at opposite sides of the second channel portion.

In some embodiments, the first drain electrode and the second source electrode may be formed integrally and disposed on a same underlying layer, and the integrally formed first drain electrode and second source electrode together may have a circular, rounded, oval, or elliptical shape in the plan view.

In some embodiments, the integrated gate electrode may further include at least one connection portion connected between the first gate electrode and the second gate electrode. The first gate electrode, the second gate electrode, and the at least one connection portion together may form the closed loop shape of the integrated gate electrode.

In some embodiments, the first channel portion of the first active layer and the second channel portion of the second active layer may be separated from each other by at least one opening portion. The at least one connection portion of the integrated gate electrode may overlap the at least one opening portion in the plan view.

In some embodiments, the first channel portion may have a U shape, and the second channel portion may have an inverted U shape in the plan view. The first gate electrode may have a U shape, and the second gate electrode may have an inverted U shape in a plan view.

In some embodiments, the closed loop shape of the integrated gate electrode may be a shape of a circular ring, an oval ring, an elliptical ring, or a rectangular ring with rounded corners in the plan view.

In some embodiments, the second channel portion may have a larger planar area than the first channel portion in the plan view.

It is to be understood that both the foregoing general description and the following detailed description are by way of example and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the present disclosure.

FIG. 1 is a plan view of a thin film transistor substrate according to an example embodiment of the present disclosure.

FIG. 2 is a cross-sectional view taken along line I-I′ in FIG. 1.

FIG. 3 is a cross-sectional view of a thin film transistor substrate according to another example embodiment of the present disclosure.

FIG. 4 is a cross-sectional view of a thin film transistor substrate according to another example embodiment of the present disclosure.

FIG. 5 is a cross-sectional view of a thin film transistor substrate according to another example embodiment of the present disclosure.

FIGS. 6A to 6D are plan views of thin film transistor substrates according to other example embodiments of the present disclosure.

FIG. 7 is a schematic diagram of a display apparatus according to another example embodiment of the present disclosure.

FIG. 8 is a block diagram schematically illustrating some stages of a gate driver according to an example embodiment of the present disclosure.

FIG. 9 is a circuit diagram showing the configuration of each stage according to an example embodiment of the present disclosure.

FIG. 10 is an example circuit diagram for one example pixel of FIG. 7.

### DETAILED DESCRIPTION

Advantages and features of the present disclosure and implementation methods thereof will be clarified through the following example embodiments described with reference to the accompanying drawings. The present disclosure may, however, be embodied in different forms and should not be construed as limited to the embodiments set forth herein. Rather, these example embodiments are provided so that this disclosure will be more thorough and complete and will more fully convey the scope of the present disclosure to those skilled in the art. Further, the protected scope of the present disclosure may be defined by the claims and their equivalents.

A shape, a size, a ratio, an angle and a number disclosed in the drawings for describing example embodiments of the present disclosure are merely examples. Thus, the present disclosure is not limited to the illustrated details. Like reference numerals refer to like elements throughout the specification, unless otherwise specified. In the following description, where the detailed description of the relevant known function or configuration may unnecessarily obscure features or aspects of the present disclosure, the detailed description of such known function or configuration may be omitted.

In a case where terms like “comprise,” “have,” and “include” are used in describing the present disclosure, another portion or element may be added unless a more limiting term like “only˜” is used. The terms of a singular form may include plural forms, and vice versa, unless referred to the contrary.

In construing an element, the element should construed as including an error band although there is no explicit description.

In describing a position relationship, for example, where the position relationship between two portions is described as “upon˜,” “above˜,” “below˜,” and “next to˜,” one or more portions may be disposed between the two portions unless a more limiting term like “just” or “direct” is used.

Spatially relative terms, such as “below,” “beneath,” “lower,” “above,” and “upper” may be used herein to describe a relationship of one element or elements to another element or elements as illustrated in the drawings. It should be understood that these terms are intended to encompass different orientations of the device in addition to the orientation depicted in the drawings. For example, if the device illustrated in the figure is reversed, the device described to be arranged “below” or “beneath” one other device may be arranged “above” the other device. Therefore, an example term “below or beneath” may include “below or beneath” and “above” orientations. Likewise, an example term “above” or “on” may include “above” and “below or beneath” orientations.

In describing a temporal relationship, for example, where the temporal order is described as “after,” “subsequent,” “next,” and “before,” a case which is not continuous may be included, unless a more limiting term “just” or “direct” is used.

It should be understood that, although such terms as “first,” “second,” etc., may be used herein to describe various elements, these elements should not be limited by these terms. These terms are only used to refer to one element separately from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements, as well as each of the first, second and third elements.

Features of various embodiments of the present disclosure may be partially or wholly coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the description of example embodiments of the present disclosure, a source electrode and a drain electrode are distinguished for convenience of description, and the source electrode and the drain electrode may be interchanged. The source electrode may be the drain electrode, and vice versa. In addition, the source electrode of any one example embodiment may be a drain electrode in another embodiment, and the drain electrode of any one example embodiment may be a source electrode in another embodiment.

In some embodiments of the present disclosure, for convenience of description, a source area may be distinguished from a source electrode, and a drain area may be distinguished from a drain electrode, but embodiments of the present disclosure are not limited thereto. The source area may be the source electrode, and the drain area may be the drain electrode. In addition, the source area may be the drain electrode, and the drain area may be the source electrode.

Reference will now be made in detail to various embodiments of the present disclosure, examples of which are illustrated in the accompanying drawings.

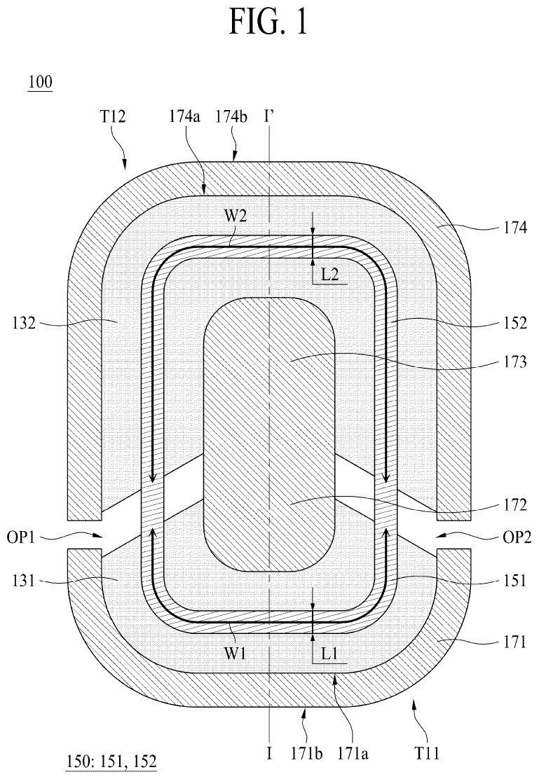

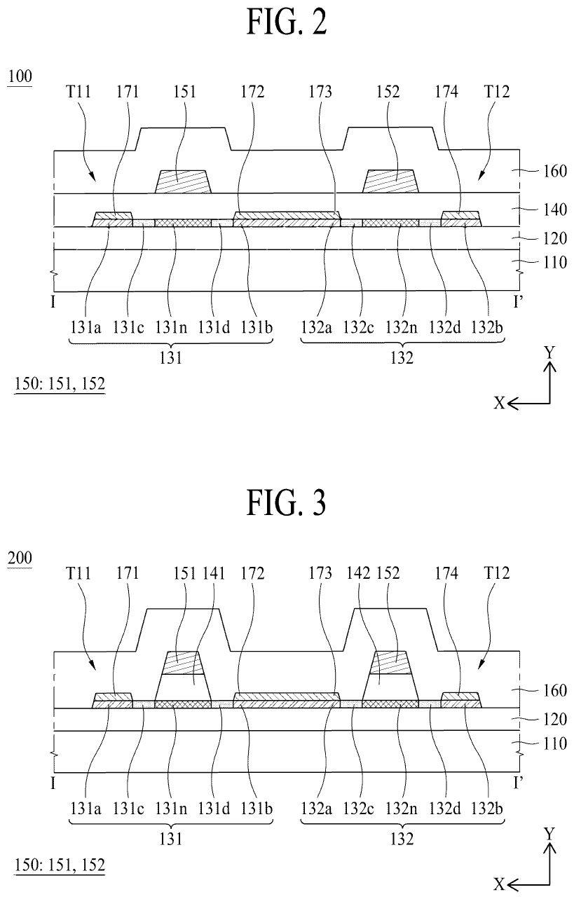

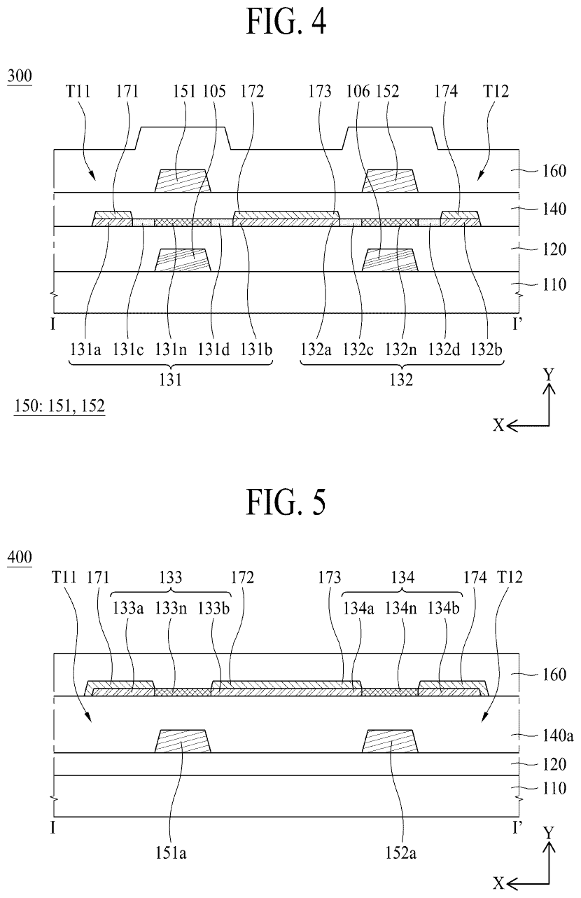

FIG. 1 is a plan view of a thin film transistor substrate 100 according to an example embodiment of the present disclosure. FIG. 2 is a cross-sectional view taken along line I-I′ in FIG. 1. FIG. 3 is a cross-sectional view of a thin film transistor substrate 200 according to another example embodiment of the present disclosure. FIG. 4 is a cross-sectional view of a thin film transistor substrate 300 according to another example embodiment of the present disclosure. FIG. 5 is a cross-sectional view of a thin film transistor substrate 400 according to another example embodiment of the present disclosure.

The thin film transistor substrate 100 according to an example embodiment of the present disclosure is disposed on a base substrate 110.

A thin film transistor substrate 100 according to an example embodiment of the present disclosure may include a first thin film transistor T11 and a second thin film transistor T12 connected in series with each other.

A first thin film transistor T11 according to an example embodiment of the present disclosure includes a first active layer 131, a first gate electrode 151, a first source electrode 171, and a first drain electrode 172. A second thin film transistor T12 includes a second active layer 132, a second gate electrode 152, a second source electrode 173, and a second drain electrode 174.

The components of the first thin film transistor T11 and the second thin film transistor T12 are described in detail below.

Glass or plastic may be used as the base substrate 110. A transparent plastic having flexible properties, such as polyimide, may be used as the plastic for the base substrate.

A first light-blocking layer 105 and a second light-blocking layer 106 may be disposed on a base substrate 110 (see FIG. 4). The first light-blocking layer 105 and the second light-blocking layer 106 block light incident from the base substrate 110 to protect the first active layer 131 and the second active layer 132. If another structure functions as a light blocker, the first light-blocking layer 105 and the second light-blocking layer 106 may be omitted.

According to an example embodiment of the present disclosure, the first light-blocking layer 105 may have a closed loop shape while overlapping the first gate electrode 151. In addition, the second light-blocking layer 106 may have a closed loop shape while overlapping the second gate electrode 152.

According to an example embodiment of the present disclosure, a buffer layer 120 may be disposed on a base substrate 110.

The buffer layer 120 may have insulating properties and protect the first active layer 131 and the second active layer 132. The buffer layer 120 may include at least one of silicon oxide (SiOx), silicon nitride (SiNx), and metal oxide having insulating properties.

In FIGS. 2 to 5, the buffer layer 120 is illustrated as a single layer, but embodiments of the present disclosure are not limited thereto. The buffer layer 120 may include a plurality of layers. In addition, another layer may be disposed between the base substrate 110 and the buffer layer 120, and another layer may be disposed between the buffer layer 120 and the first active layer 131 and the second active layer 132.

According to an example embodiment of the present disclosure, the first active layer 131 and the second active layer 132 are disposed on the buffer layer 120.

The first active layer 131 includes a first channel portion 131n, a first source conductor portion 131a disposed at one side of the first channel portion 131n, and a first drain conductor portion 131b disposed at the other side of the first channel portion 131n. The second active layer 132 includes a second channel portion 132n, a second source conductor portion 132a disposed at one side of the second channel portion 132n, and a second drain conductor portion 132b disposed at the other side of the second channel portion 132n.

For example, the first channel portion 131n is disposed between the first source conductor portion 131a and the first drain conductor portion 131b, and the second channel portion 132n is disposed between the second source conductor portion 132a and the second drain conductor portion 132b.

The first active layer 131 may further include a first source connection portion 131c disposed between the first channel portion 131n and the first source conductor portion 131a and include a first drain connection portion 131d disposed between the first channel portion 131n and the first drain conductor portion 131b.

The second active layer 132 may further include a second source connection portion 132c disposed between the second channel portion 132n and the second source conductor portion 132a and include a second drain connection portion 132d disposed between the second channel portion 132n and the second drain conductor portion 132b.

The first active layer 131 and the second active layer 132 may include an oxide semiconductor material.

The oxide semiconductor material may include, for example, at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, embodiments of the present disclosure are not limited thereto, and the first active layer 131 and the second active layer 132 may be formed of other oxide semiconductor materials known in the art.

The first source connection portion 131c and the first drain connection portion 131d of the first active layer 131 may be formed by selectively conductorizing the first active layer 131 made of a semiconductor material. According to an example embodiment of the present disclosure, selective conductorization refers to imparting conductivity to a specific portion of an active layer (the first active layer 131 here) so that it can function like a conductor. The second source connection portion 132c and the second drain connection portion 132d of the second active layer 132 may also be formed by selectively conductorizing the second active layer 132 made of a semiconductor material.

For example, the first active layer 131 and the second active layer 132 can be selectively conductorized by ion doping. As a result, the first source connection portion 131c, the first drain connection portion 131d, the second source connection portion 132c, and the second drain connection portion 132d can be formed. However, embodiments of the present disclosure are not limited thereto, and the first active layer 131 and the second active layer 132 can also be selectively conductorized by other methods known in the art.

The first source connection portion 131c, the first drain connection portion 131d, the second source connection portion 132c, and the second drain connection portion 132d do not overlap the first gate electrode 151 or the second gate electrode 152. The first source connection portion 131c, the first drain connection portion 131d, the second source connection portion 132c, and the second drain connection portion 132d have superior electrical conductivity and higher mobility compared to the first channel portion 131n and the second channel portion 132n. Therefore, the first source connection portion 131c, the first drain connection portion 131d, the second source connection portion 132c, and the second drain connection portion 132d can each function as wiring.

According to example embodiment of the present disclosure, the first drain conductor portion 131b and the second source conductor portion 132a may be formed integrally.

The first active layer 131 and the second active layer 132 may have a multilayer structure.

According to an example embodiment of the present disclosure, the first thin film transistor T11 may further include a first source electrode 171 and a first drain electrode 172 that are disposed in contact with the first active layer 131 and spaced apart from each other. In addition, the second thin film transistor T12 may include a second source electrode 173 and a second drain electrode 174 that are disposed in contact with the second active layer 132 and spaced apart from each other.

For example, the first source electrode 171 and the first drain electrode 172 are disposed spaced apart from each other while being in contact with the first source conductor portion 131a and the first drain conductor portion 131b of the first active layer 131, respectively, and the second source electrode 173 and the second drain electrode 174 are disposed spaced apart from each other while being in contact with the second source conductor portion 132a and the second drain conductor portion 132b of the second active layer 132, respectively.

According to an example embodiment of the present disclosure, the first source electrode 171, the first drain electrode 172, the second source electrode 173, and the second drain electrode 174 may each include at least one selected from titanium (Ti), molybdenum (Mo), aluminum (Al), silver (Ag), copper (Cu), chromium (Cr), tantalum (Ta), neodymium (Nd), calcium (Ca), and barium (Ba).

The first source electrode 171, the first drain electrode 172, the second source electrode 173, and the second drain electrode 174 may have reducibility. The first active layer 131 may be selectively conductorized by the first source electrode 171 and the first drain electrode 172. The second active layer 132 may be selectively conductorized by the second source electrode 173 and the second drain electrode 174. According to an example embodiment of the present disclosure, the first source conductive portion 131a and the first drain conductive portion 131b are in contact with the first source electrode 171 and the first drain electrode 172, respectively. The region of the first active layer 131 that comes into contact with the first source electrode 171 and the first drain electrode 172 can be conductorized to form a first source conductor portion 131a and a first drain conductor portion 131b, respectively.

Specifically, according to an example embodiment of the present disclosure, portions of the first active layer 131 that are in contact with the first source electrode 171 and the first drain electrode 172 may be reduced, respectively, to create a first source conductor portion 131a and a first drain conductor portion 131b. In addition, portions of the second active layer 132 that are in contact with the second source electrode 173 and the second drain electrode 174 may be reduced, respectively, to create a second source conductor portion 132a and a second drain conductor portion 132b.

For example, when portions of the first active layer 131 and the second active layer 132 that are respectively in contact with and overlap the first source electrode 171, the first drain electrode 172, the second source electrode 173, and the second drain electrode 174 are reduced, oxygen vacancies are generated in those portions of the first active layer 131 and the second active layer 132. Accordingly, the first active layer 131 and the second active layer 132 can be selectively conductorized. By this selective reduction of the first active layer 131 and the second active layer 132, a first source conductor portion 131a, a first drain conductor portion 131b, a second source conductor portion 132a, and a second drain conductor portion 132b can be created.

In general, a dual gate structure has been used to overcome the stress situation where high drain bias is applied inside the transistor. Specifically, a dual gate structure in which two gates are disposed in series has been used to distribute voltage.

Here, in a dual-gate structure where two gates are connected in series, the voltage applied to each gate may not always be equal. For example, a higher voltage may be applied to the gate of a transistor to which a higher voltage is applied among the two transistors. In other words, an electric field may be concentrated in the active layer of the transistor to which a higher voltage is applied, causing deterioration. Specifically, an electric field may be concentrated in the drain region of the active layer of the transistor to which a higher voltage is applied, causing deterioration.

According to an example embodiment of the present disclosure, to prevent or suppress deterioration concentration on the drain region of the transistor to which a higher potential voltage is applied, the second drain electrode 174 may have a larger planar area than the second source electrode 173 (in a plan view). Here, the higher potential voltage may be applied to the second thin film transistor T12.

Specifically, the second drain electrode 174 of the second thin film transistor T12 to which a higher potential voltage is applied can be formed relatively wider than the second source electrode 173, thereby reducing the voltage applied to the second gate electrode 152 of the second thin film transistor T12. As a result, the electric field effect concentrated on the second drain conductor portion 132b and the second drain connection portion 132d of the second active layer 132 can be reduced, and deterioration in the second thin film transistor T12 can be prevented or suppressed.

According to an example embodiment of the present disclosure, the first source electrode 171 of the first thin film transistor T11 may have a larger planar area than the first drain electrode 172 (in a plan view). Specifically, the first drain electrode 172 of the first thin film transistor T11 may be formed relatively narrower than the first source electrode 171 to increase the voltage applied to the first gate electrode 151 of the first thin film transistor T11. As a result, the voltage applied to the second gate electrode 152 of the second thin film transistor T12 may decrease by the amount by which the voltage applied to the first gate electrode 151 of the first thin film transistor T11 increases.

Due to this, the electric field effect concentrated on the second drain conductor portion 132b and the second drain connection portion 132d of the second active layer 132 can be reduced, and deterioration in the second thin film transistor T12 can be prevented or suppressed.

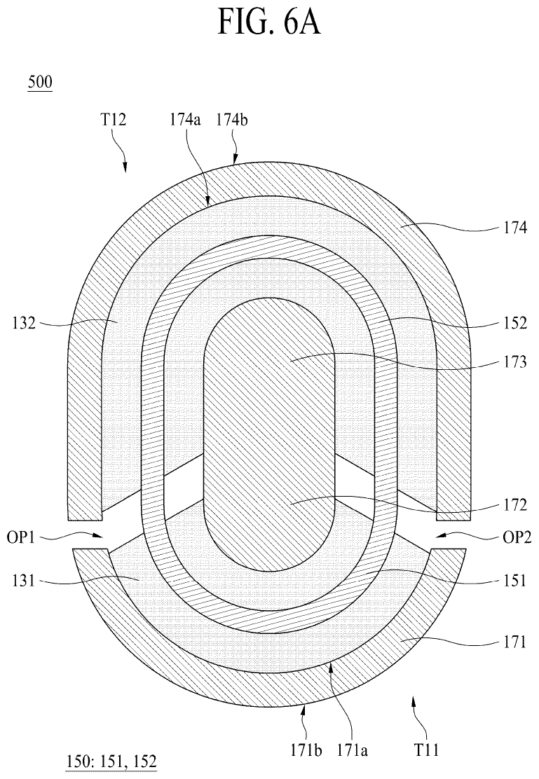

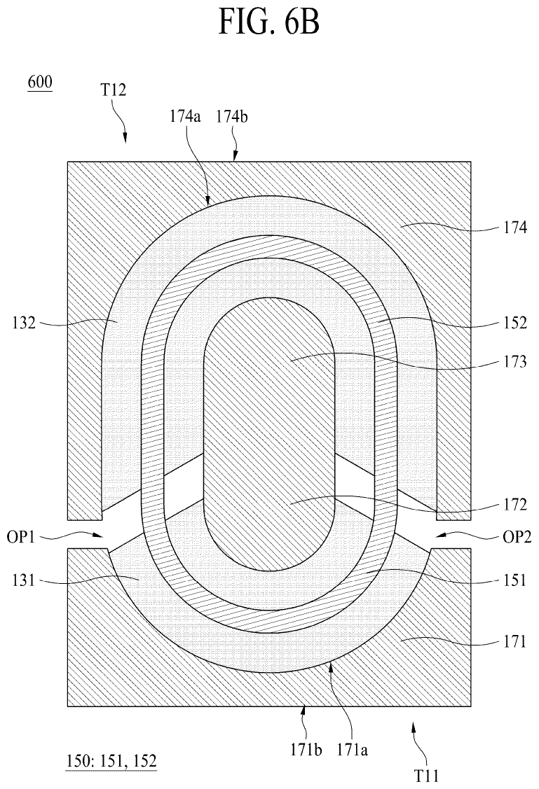

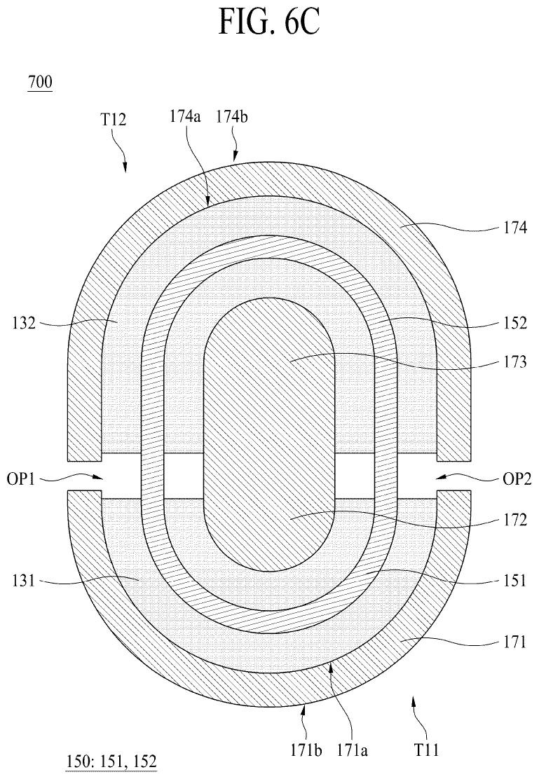

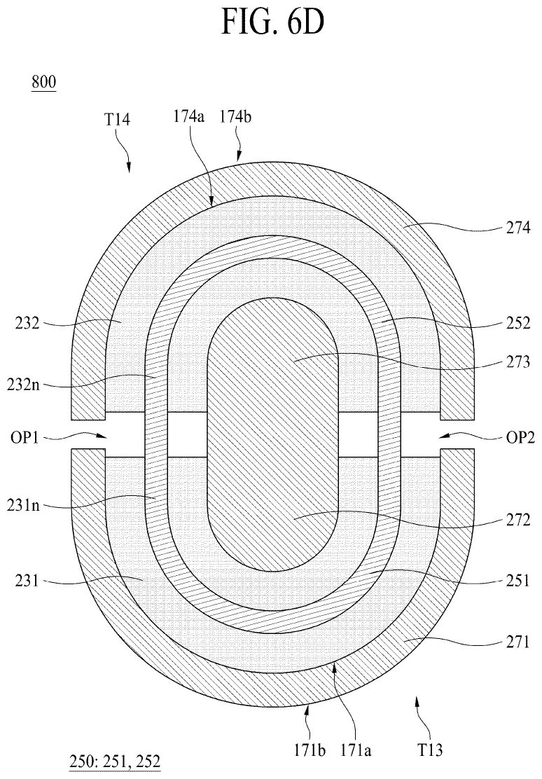

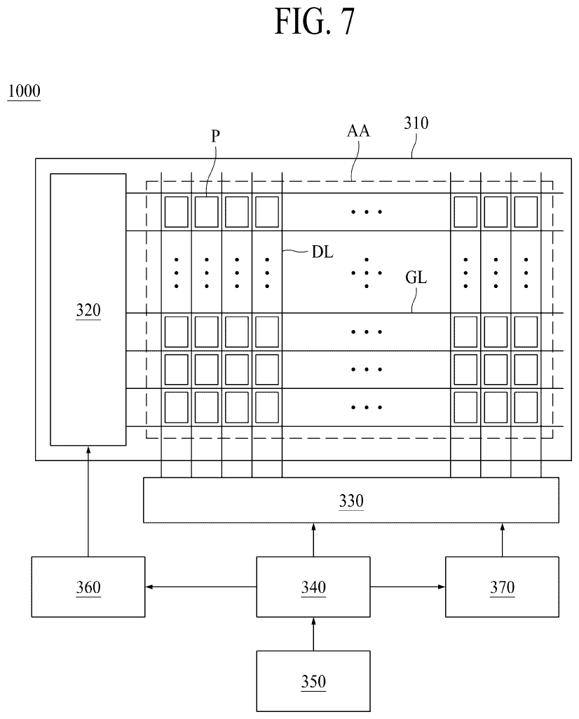

According to an example embodiment of the present disclosure, the first drain electrode 172 and the second source electrode 173 are formed integrally. Specifically, the first drain electrode 172 and the second source electrode 173 may have, for example, a circular shape, a square or rectangular shape with rounded corners, an oval shape, or an elliptical shape, as shown for example in FIGS. 1, 6A, and 6C.

According to an example embodiment of the present disclosure, since the first drain electrode 172 and the second source electrode 173 are formed integrally, the area occupied by the thin film transistor substrate 100 can be reduced. For example, where the thin film transistor substrate 100 according to an example embodiment of the present disclosure is provided in a gate driver of a display apparatus, the display apparatus of the present disclosure can implement a narrower bezel.

According to an example embodiment of the present disclosure, the first source electrode 171 may be formed in a U shape, and the second drain electrode 174 may be formed in a U shape rotated by 180°. For example, the second drain electrode 174 may have an inverted U shape. In this example case, the second drain electrode 174 may have a larger planar area compared to the first source electrode 171 in a plane.

According to an example embodiment of the present disclosure, the first thin film transistor T11 may further include a first gate electrode 151 that is disposed spaced apart (or insulated) from the first active layer 131 and overlaps the first active layer 131. The second thin film transistor T12 may further include a second gate electrode 152 that is disposed spaced apart (or insulated) from the second active layer 132 and overlaps the second active layer 132.

The first gate electrode 151 and the second gate electrode 152 may each include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). Although not shown in the drawing, the first gate electrode 151 and the second gate electrode 152 may also each have a multilayer film structure including two or more conductive films having different physical properties.

According to an example embodiment of the present disclosure, the first gate electrode 151 may be formed in a U shape. The second gate electrode 152 may be formed in an inverted U shape.

As illustrated in FIG. 1, the first gate electrode 151 and the second gate electrode 152 may integrally form the gate electrode 150. For example, the gate electrode 150 may include the first gate electrode 151 and the second gate electrode 152. The gate electrode 150 may have a ring shape. For example, the gate electrode 150 may have a circular or oval ring shape. For example, the gate electrode 150 may have a closed loop shape. For example, the first gate electrode 151 and the second gate electrode 152 may integrally form a closed loop shape.

In the example embodiment shown in FIG. 1, the first gate electrode 151 means a region that overlaps the first active layer 131 in a plane. In addition, the second gate electrode 152 means a region that overlaps the second active layer 132 in a plane. Here, the gate electrode 150 may include a connection portion that does not overlap either the first active layer 131 or the second active layer 132.

For example, the region of the gate electrode 150 that overlaps with the first active layer 131 may be referred to as the first gate electrode 151, and the region that overlaps with the second active layer 132 may be referred to as the second gate electrode 152.

According to an example embodiment of the present disclosure, the second gate electrode 152 may have a larger planar area than the first gate electrode 151. When the area of the second gate electrode 152 of the second thin film transistor T12 is larger than the area of the first gate electrode 151 of the first thin film transistor T11, it is possible to prevent or suppress an electric field from being concentrated on the second active layer 132 of the second thin film transistor T12. As a result, it is possible to prevent or suppress deterioration of the thin film transistor substrate 100 according to embodiments of the present disclosure.

According to an example embodiment of the present disclosure, the first drain electrode 172 and the second source electrode 173 are disposed on the inside of the first gate electrode 151 and the second gate electrode 152 which are formed integrally in a plane. For example, the first drain electrode 172 and the second source electrode 173 are disposed in the area surrounded by the first gate electrode 151 and the second gate electrode 152 (or the gate electrode 150) which are formed integrally in a plane.

Since the first drain electrode 172 and the second source electrode 173 are disposed inside the first gate electrode 151 and the second gate electrode 152 that are formed as parts of one integrated body, the area occupied by the thin film transistor substrate 100 can be reduced. For example, where the thin film transistor substrate 100 according to an example embodiment of the present disclosure is provided in a gate driver of a display apparatus, the display apparatus of the present disclosure can implement a narrower bezel.

According to an example embodiment of the present disclosure, the second channel portion 132n may have a larger planar area than the first channel portion 131n (in a plan view). For example, where the area of the second channel portion 132n is larger than that of the first channel portion 131n, the resistance in the second channel portion 132n may be reduced compared to the resistance in the first channel portion 131n, thereby reducing the occurrence of deterioration in the second thin film transistor T12.

For example, as illustrated in FIG. 1, the first channel portion 131n may have a first length L1 and a first width W1 that is perpendicular to the first length L1 and extends along the first channel portion 131n overlapping the first gate electrode 151. The second channel portion 132n may have a second length L2 and a second width W2 that is perpendicular to the second length L2 and extends along the second channel portion 132n overlapping the second gate electrode 152. In this case, the second width W2 of the second channel portion 132n may be longer than the first width W1 of the first channel portion 131n.

The first length L1 according to an example embodiment of the present disclosure may be the shortest length between the first source connection portion 131c and the first drain connection portion 131d. For example, when the first source connection portion 131c and the first drain connection portion 131d do not exist, it may be the shortest length between the first source conductor portion 131a and the first drain conductor portion 131b. The description of the second length L2 according to the present disclosure is omitted because it is similar as and overlaps with the first length L1.

The first width W1 according to an example embodiment of the present disclosure may be the length of a region that is perpendicular to the first length L1 and extends along the first channel portion 131n. The description of the second width W2 according to an example embodiment of the present disclosure is omitted because it is similar as and overlaps with the first width W1.

According to an example embodiment of the present disclosure, the first length L1 and the second length L2 can be equal.

According to an example embodiment of the present disclosure, the first width W1 (extending along the first channel portion 131n) may be smaller than the second width W2 (extending along the second channel portion 132n). Also, for example, the first width W1 may become smaller as the first channel portion 131n is disposed closer toward the first drain conductor portion 131b in a plane. The second width W2 may become larger as the second channel portion 132n is disposed closer toward the second drain conductor portion 132b in a plane. For example, the first width W1 may become shorter as the first channel portion 131n is disposed farther away from the first source conductor portion 131a or closer to the first drain conductor portion 131b. For example, the second width W2 may become longer as the second channel portion 132n is disposed farther away from the second source conductor portion 132a or closer to the second drain conductor portion 132b.

An electric field is concentrated on the second drain conductor portion 132b to which a relatively high voltage is applied. Physical or electrical deterioration may occur in the area where such electric field concentration occurs. As the second width W2 becomes longer with the second channel portion 132n being disposed closer toward the second drain conductor portion 132b in a plane, the electric field concentration in the second drain conductor portion 132b may be more alleviated.

According to an embodiment of the present disclosure, the first channel portion 131n may be formed in a U shape. The second channel portion 132n may be formed in an inverted U shape. The first channel portion 131n overlaps the first gate electrode 151 in a plan view, and the second channel portion 132n overlaps the second gate electrode 152 in a plan view.

According to an example embodiment of the present disclosure, the first channel portion 131n and the second channel portion 132n may be disposed with opening portions OP1, OP2 (e.g., portions where no active layer is disposed) therebetween. Specifically, the opening portions OP1, OP2 include a first opening portion OP1 and a second opening portion OP2. The first opening portion OP1 and the second opening portion OP2 are disposed spaced apart from each other with a first drain electrode 172 and a second source electrode 173 therebetween. FIG. 1 illustrates an example configuration in which the first opening portion OP1 and the second opening portion OP2 are not parallel to each other and are symmetrical with each other with the first drain electrode 172 and the second source electrode 173 therebetween. However, embodiments of the present disclosure are not limited thereto, and the first opening portion OP1 and the second opening portion OP2 may be parallel to each other and symmetrical to each other with the first drain electrode 172 and the second source electrode 173 interposed therebetween (see, for example, FIG. 6C). For example, the first opening portion OP1 and the second opening portion OP2 may be disposed along the same line, respectively.

According to an example embodiment of the present disclosure, the first source electrode 171 and the second drain electrode 174 are disposed with an opening or vacant area (such as the opening portions OP1, OP2) therebetween in a plane.

According to an example embodiment of the present disclosure, a gate insulating film 140 is disposed on the first active layer 131 and the second active layer 132. Specifically, the gate insulating film 140 is disposed between the first active layer 131 and the first gate electrode 151 and between the second active layer 132 and the second gate electrode 152. However, embodiments of the present disclosure are not limited thereto. In the case of a bottom gate structure in which the first gate electrode 151a is disposed between the base substrate 110 and the first active layer 133 and the second gate electrode 152a is disposed between the base substrate 110 and the second active layer 134, the gate insulating film 140a may be disposed on the first gate electrode 151a and the second gate electrode 152a (see, e.g., FIG. 5).

According to an example embodiment of the present disclosure, the gate insulating film 140 can cover the entire upper surfaces of the first active layer 131 and the second active layer 132. FIG. 2 illustrates that the gate insulating film 140 covers the entire upper surfaces of the first active layer 131 and the second active layer 132. However, embodiments of the present disclosure are not limited thereto, and the gate insulating film 140 can expose a part of the upper surfaces of the first active layer 131 and the second active layer 132. For example, as illustrated, e.g., in FIG. 3, the first gate insulating film 141 and the second gate insulating film 142 can expose the first source connection portion 131c, the first drain connection portion 131d, the second source connection portion 132c, and the second drain connection portion 132d, respectively.

The gate insulating film 140 may include at least one of silicon oxide, silicon nitride, and metal oxide. The gate insulating film 140 may have a single film structure or a multilayer film structure. The gate insulating film 140 protects the first active layer 131 and the second active layer 132.

According to an example embodiment of the present disclosure, a first gate electrode 151 and a second gate electrode 152 may be disposed on a gate insulating film 140. However, embodiments of the present disclosure are not limited thereto. In the case of a bottom gate structure, a first active layer 133 and a second active layer 134 may be disposed on a gate insulating film 140a (see, e.g., FIG. 5).

An interlayer insulating film 160 is disposed on the first gate electrode 151 and the second gate electrode 152. The interlayer insulating film 160 is an insulating layer made of an insulating material. Specifically, the interlayer insulating film 160 may be made of an organic material, an inorganic material, or a laminate of an organic material layer and an inorganic material layer.

According to an example embodiment of the present disclosure, the first source electrode 171, the first drain electrode 172, the second source electrode 173, and the second drain electrode 174 may be disposed on the same layer. For example, the first source electrode 171, the first drain electrode 172, the second source electrode 173, and the second drain electrode 174 may be disposed on the first active layer 131 and the second active layer 132, respectively. For example, the first source electrode 171, the first drain electrode 172, the second source electrode 173, and the second drain electrode 174 may be disposed on a different layer from the first gate electrode 151 and the second gate electrode 152.

According to an example embodiment of the present disclosure, illustrated, e.g., in FIG. 4, the first thin film transistor T11 may further include a first light-blocking layer 105 disposed between the base substrate 110 and the first active layer 131. The second thin film transistor T12 may further include a second light-blocking layer 106 disposed between the base substrate 110 and the second active layer 132.

For example, as shown in FIG. 4, in a top gate structure in which a first active layer 131 is disposed between a base substrate 110 and a first gate electrode 151, and a second active layer 132 is disposed between the base substrate 110 and a second gate electrode 152, a first light-blocking layer 105 and a second light-blocking layer 106 may be disposed on the base substrate 110. The first light-blocking layer 105 and the second light-blocking layer 106 may protect the first channel portion 131n and the second channel portion 132n from the outside, respectively.

According to an example embodiment of the present disclosure, the first light-blocking layer 105 and the second light-blocking layer 106 may each be a gate electrode. For example, the first light-blocking layer 105 and the second light-blocking layer 106 may each function as a lower gate electrode. Here, the first light-blocking layer 105 may be electrically connected to the first gate electrode 151, and the second light-blocking layer 106 may be electrically connected to the second gate electrode 152. In other words, the first thin film transistor T11 and the second thin film transistor T12 may each have a double gate structure.

As illustrated in FIG. 5, the first thin film transistor (T11) may include a first active layer (133) and a first gate electrode (151a), and the second thin film transistor (T12) may include a second active layer (134) and a second gate electrode (152a). The first active layer (133) includes a first channel portion (133n), a first source conductor portion (133a) disposed at one side of the first channel portion (133n), and a first drain conductor portion (133b) disposed at the other side of the first channel portion (133n). The second active layer (134) includes a second channel portion (134n), a second source conductor portion (134a) disposed at one side of the second channel portion (134n), and a second drain conductor portion (134b) disposed at the other side of the second channel portion (134n). The first channel portion (133n), first source conductor portion (133a), first drain conductor portion (133b), second channel portion (134n), second source conductor portion (134a), and second drain conductor portion (134b) shown in FIG. 5 may correspond to the first channel portion (131n), first source conductor portion (131a), first drain conductor portion (131b), second channel portion (132n), second source conductor portion (132a), and second drain conductor portion (132b) shown in FIG. 2, respectively. In addition, the first source electrode (171), first drain electrode (172), second source electrode (173), and second drain electrode (174) shown in FIG. 5 correspond to the first source electrode (171), first drain electrode (172), second source electrode (173), and second drain electrode (174) shown in FIG. 2, respectively.

FIGS. 6A to 6D are respective plan views of thin film transistor substrates 500, 600, 700, 800 according to other example embodiments of the present disclosure.

According to an example embodiment of the present disclosure, the first gate electrode 151 and the second gate electrode 152 may integrally form any closed loop shape, including any one of a circular ring, an elliptical ring, and a square or rectangular ring with rounded corners in a plane. For example, the gate electrode 150 formed of the first gate electrode 151 and the second gate electrode 152 may be formed as any one of a circular ring, an elliptical ring, and a square ring with rounded corners.

In FIG. 1, the first gate electrode 151 and the second gate electrode 152 are shown as integrally forming a rectangular ring with rounded vertices or corners. In FIGS. 6A to 6C, the first gate electrode 151 and the second gate electrode 152 are shown as integrally forming an elliptical ring.

When the first gate electrode 151 and the second gate electrode 152 are integrally formed into a polygonal ring shape, the lengths of the first channel portion 131n and the second channel portion 132n may increase at the vertices of the polygon. As a result, an electric field may be concentrated at the vertices of the first gate electrode 151 and the second gate electrode 152, which may cause a problem in that deterioration may occur at the vertices of the first gate electrode 151 and the second gate electrode 152.

According to an example embodiment of the present disclosure, the first source electrode 171 may have an inner surface 171a and an outer surface 171b. Additionally, the second drain electrode 174 may have an inner surface 174a and an outer surface 174b.

According to an example embodiment of the present disclosure, each edge of the inner surface 171a of the first source electrode 171 and the inner surface 174a of the second drain electrode 174 may have a rounded shape or curved shape in a plane. In an example embodiment of the present disclosure, the inner surface may mean a side surface facing the gate electrode 150 in a plane.

As shown in FIGS. 6A to 6C, each edge of the inner surface 171a of the first source electrode 171 and the inner surface 174a of the second drain electrode 174 may have a round shape. For example, even with the first gate electrode 151 and the second gate electrode 152 integrally formed into a circular, oval, or elliptical ring shape, if one or more edges of the inner surface 171a of the first source electrode 171 and the inner surface 174a of the second drain electrode 174 has a certain angle, the length of the conductive region may become longer in the region having the certain angle, and a problem of increased resistance may occur.

However, the outer surface 171b of the first source electrode 171 and the outer surface 174b of the second drain electrode 174 may each have a round shape or may have an angled shape.

For example, FIGS. 6A and 6C illustrate examples in which the outer surface 171b of the first source electrode 171 and the outer surface 174b of the second drain electrode 174 each have a round shape.

For example, FIG. 6B illustrates an example in which the outer surface 171b of the first source electrode 171 and the outer surface 174b of the second drain electrode 174 each have pointed corners or vertices with angles.

As illustrated in FIG. 6D, the thin film transistor substrate 800 may include a third thin film transistor T13 and a fourth thin film transistor T14 connected in series with each other.

The third thin film transistor T13 includes a third active layer 231 having a third channel portion 231n, a third gate electrode 251 spaced apart or insulated from the third active layer 231 and overlapping the third active layer 231, and a third source electrode 271 and a third drain electrode 272 that are spaced apart from each other and in contact with the third active layer 231.

The fourth thin film transistor T14 includes a fourth active layer 232 having a fourth channel portion 232n, a fourth gate electrode 252 spaced apart or insulated from the fourth active layer 232 and overlapping the fourth active layer 232, and a fourth source electrode 273 and a fourth drain electrode 274 that are in contact with the fourth active layer 232 and spaced apart from each other.

In the thin film transistor substrate 800 according to FIG. 6D, compared to the thin film transistor substrate 100 according to FIG. 1, the third channel portion 231n may have the same planar area as the fourth channel portion 232n in a plane, the third source electrode 271 and the fourth drain electrode 274 may have the same planar area in a plane, and the third gate electrode 251 and the fourth gate electrode 252 may have the same planar area in a plane.

In plan view, the third source electrode 271 may have the same area as the fourth drain electrode 274. For example, in plan view, the third gate electrode 251 and the fourth gate electrode 252 may have the same area. For example, in plan view, the third active layer 231 and the fourth active layer 232 may have the same area.

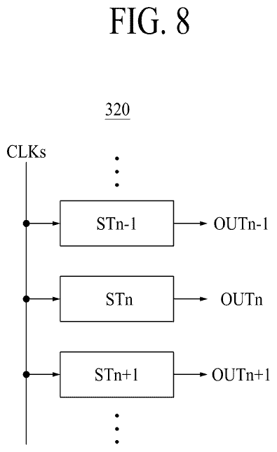

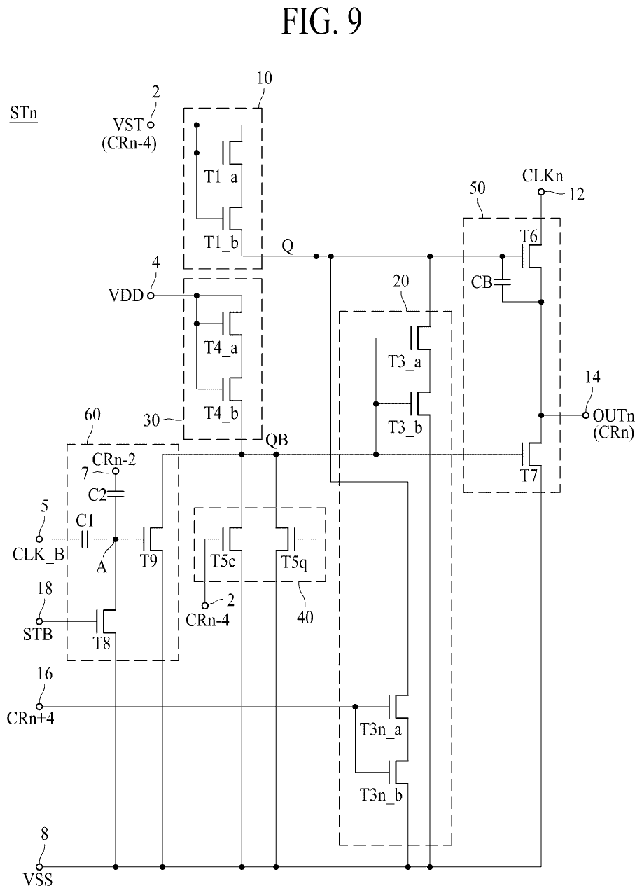

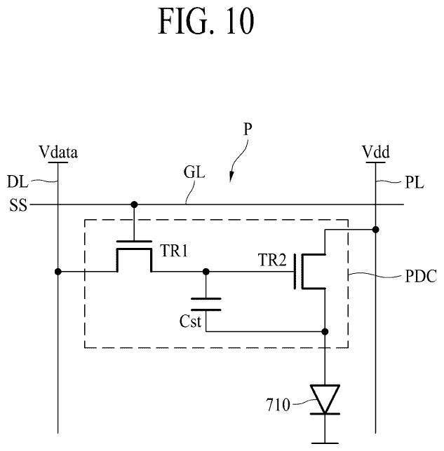

FIG. 7 is a schematic diagram of a display apparatus 1000 according to another example embodiment of the present disclosure. FIG. 8 is a block diagram schematically showing some stages of a gate driver 320 according to an example embodiment of the present disclosure. FIG. 9 is a circuit diagram showing the configuration of each stage STn according to an example embodiment of the present disclosure. FIG. 10 is an example circuit diagram for one example pixel P of FIG. 7.

As illustrated in FIG. 7, the display apparatus 1000 may include a display panel 310, a gate driver 320 (e.g., a GIP type gate driver), a data driver 330, a timing controller 340, a level shifter 360, a gamma voltage generator 370, a power management circuit 350, etc.

The power management circuit 350 can generate and output various driving voltages for the operation of all components of the display apparatus 1000, such as the display panel 310, gate driver 320, data driver 330, timing controller 340, level shifter 360, gamma voltage generator 370, etc., by using an input voltage supplied from an external source.

The timing controller 340 can receive image data and synchronization signals from an external host system. The timing controller 340 can perform various image processing, such as brightness correction for reducing power consumption or image quality correction, on the image data and supply the processed image data to the data driver 330. The timing controller 340 can generate a plurality of data control signals using synchronization signals and internally stored timing setting information (start timing, pulse width, etc.) and supply the generated data to the data driver 330, and can also generate a plurality of control signals and supply the generated control signals to the level shifter 360.

The gamma voltage generator 370 can generate a reference gamma voltage set including a plurality of reference gamma voltages having different voltage levels and supply the set to the data driver 330.

The data driver 330 is controlled according to a data control signal supplied from the timing controller 340, converts digital data supplied from the timing controller 340 into an analog data signal, and supplies the corresponding data signal to each of the data lines of the display panel 310.

The level shifter 360 can generate a plurality of gate control signals based on a plurality of control signals supplied from the timing controller 340 and supply them to the gate driver 320. The level shifter 360 can level-shift a start signal, a reset signal, etc., supplied from the timing controller 340 and supply them to the gate driver 320.

The display panel 310 displays an image through a display area AA in which pixels P are disposed in a matrix form. Each pixel P may be composed of a combination of a red (R) subpixel that emits red light, a green (G) subpixel that emits green light, and a blue (B) subpixel that emits blue light. Each pixel P may additionally include a white (W) subpixel that emits white light.

The gate driver 320 is composed of thin film transistors disposed outside the display area AA of the display panel 310, and may be disposed in a GIP (Gate In Panel) type in a bezel area on both sides or one side of the display panel 310. Specifically, in the GIP (Gate In Panel) type, the gate driver 320 may be disposed on the base substrate 110.

The gate driver 320 can receive multiple gate control signals from the level shifter 360 and perform a shift operation to individually drive the gate lines GL of the display panel 310. The gate driver 320 may be configured as a shift register having multiple stages that are connected to each other in a cascading manner to generate individual gate outputs to individually drive the multiple gate lines GL.

For convenience, in FIG. 8, only three stages STn−1, STn, STn+1(n is a natural number that each generate three gate outputs OUTn−1, OUTn, OUTn+1, among the multiple stages constituting the gate driver 320, are schematically illustrated.

Each stage STn can be supplied with at least one clock signal among a plurality of clock signals CLKs having different phases. Each stage STn can output an input clock pulse as a scan pulse of a gate output OUTn in response to any one of a start signal and an output of a preceding stage (a set signal). Each stage STn can output a gate-off voltage of a gate output OUTn in response to any one of a reset signal and an output of a succeeding stage (a reset signal). The gate output OUTn or the carry output of each stage STn can be used as a carry signal and supplied as a set signal or a reset signal to another stage. The preceding stage means any one of the stages positioned before (above) the corresponding stage or outputting a scan pulse before the corresponding stage, and the succeeding stage means any one of the stages positioned after (below) the corresponding stage or outputting a scan pulse after the corresponding stage.

The display apparatus 1000 according to an example embodiment of the present disclosure may include any of the thin film transistor substrates 100, 200, 300, 400, 500, 600, 700, 800 described above. According to an example embodiment of the present disclosure, a gate driver 320 may include any of the thin film transistor substrates 100, 200, 300, 400, 500, 600, 700, 800 described above.

As illustrated in FIG. 9, each stage STn may include a first charging circuit 10, a first discharging circuit 20, a second charging circuit 30, a second discharging circuit 40, an output circuit 50, and a QB stabilization circuit 60. The first charging circuit 10, the first discharging circuit 20, the second charging circuit 30, the second discharging circuit 40, and the QB stabilization circuit 60 may all be defined as control circuits that control the Q node and the QB node of the output circuit 50. The Q node may be defined as the first control node, and the QB node may be defined as the second control node. For example, the control circuit may charge and discharge the Q node, and charge and discharge the QB node in a manner opposite to the Q node.

Each stage STn may include a set terminal 2 to which one of a start signal VST and an output CRn−4 of a preceding stage is applied as a set signal, a first power terminal 4 to which a high-potential voltage VDD is applied, a second power terminal 8 to which a gate-off voltage VSS is applied, a first clock terminal 12 to which a clock signal CLKn is applied, an output terminal 14 from which a gate output OUTn is outputted, a reset terminal 16 to which one of a reset signal and an output CRn+4 of a succeeding stage is applied as a reset signal, a second clock terminal 5 to which an inverted clock signal CLK_B is applied, a control terminal 7 to which an output CRn−2 of another preceding stage (e.g., an (n−2)th preceding stage) is applied, and a stabilization terminal 18 to which a stabilization signal STB is applied. The gate-off voltage VSS may be defined as a gate low voltage. The gate output OUTn of each stage STn can be output as a carry signal CRn to another stage.

The first charging circuit 10 can receive a start signal VST or an output CRn−4 of a preceding stage as a set signal through a set terminal 2, and charge the Q node with the set signal. The output CRn−4 of the preceding stage can be a gate output OUTn−4 output from the (n−4)th preceding stage.

The first charging circuit 10 may include a first Q charging transistor T1_a having a gate electrode and a drain electrode connected to the set terminal 2, and a source electrode connected to the drain electrode of a second Q charging transistor T1_b. The first charging circuit 10 may additionally include the second Q charging transistor T1_b having a gate electrode connected to the set terminal 2, a drain electrode connected to the source electrode of the first Q charging transistor T1_a, and a source electrode connected to the Q node.

The first discharge circuit 20 can discharge the Q node to the gate-off voltage VSS of the second power terminal 8 in response to the control of the QB node. The first discharge circuit 20 can receive a reset signal or an output CRn+4 of a subsequent stage as a reset signal through the reset terminal 16 to discharge the Q node to the gate-off voltage VSS of the second power terminal 8. The output CRn+4 of the subsequent stage can be a gate output OUTn+4 output from the (n+4)th subsequent stage. For example, the first discharge circuit 20 can include Q discharge transistors T3_a, T3_b that discharge the Q node to the gate-off voltage VSS by the control of the QB node. For example, the Q discharge transistors T3_a, T3_b can include a first-first Q discharge transistor T3_a and a first-second Q discharge transistor T3_b.

The first discharge circuit 20 may include the first-first Q discharge transistor T3_a having a gate electrode connected to the QB node, a source electrode connected to the drain electrode of the first-second Q discharge transistor T3_b, and a drain electrode connected to the Q node. The first discharge circuit 20 may additionally include the first-second Q discharge transistor T3_b having a gate electrode connected to the QB node, a drain electrode connected to the source electrode of the first-first Q discharge transistor T3_a, and a source electrode connected to the second power terminal 8. The first discharge circuit 20 may further include a second-first Q discharge transistor T3n_a having a gate electrode connected to a reset terminal 16 to which an output signal CRn+4 or a reset signal of a subsequent stage is supplied, a source electrode connected to a drain electrode of a second-second Q discharge transistor T3n_b, and a drain electrode connected to a Q node, and include the second-second Q discharge transistor T3n_b having a gate electrode connected to the reset terminal 16 to which an output signal CRn+4 or a reset signal of a subsequent stage is supplied, a drain electrode connected to the source electrode of the second-first Q discharge transistor T3n_a, and a source electrode connected to the second power terminal 8.

Where the Q discharge transistors T3_a, T3_b are subjected to positive bias and high temperature stress conditions, for example, PBTS (Positive Bias Temperature Stress) conditions, the active layers of the first-first Q discharge transistor T3_a and the first-second Q discharge transistor T3_b may be formed identically so that the PBTS degradation can be evenly applied to the first-first Q discharge transistor T3_a and the first-second Q discharge transistor T3_b.

According to an example embodiment of the present disclosure, the Q discharge transistors T3_a, T3_b may include the thin film transistor substrate 800 illustrated in FIG. 6D. For example, the first-first Q discharge transistor T3_a may be the fourth thin film transistor T14 of the thin film transistor substrate 800, and the first-second Q discharge transistor T3_b may be the third thin film transistor T13 of the thin film transistor substrate 800. The third thin film transistor T13 and the fourth thin film transistor T14 are connected in series with each other.

In an example embodiment where the first-first Q discharge transistor T3_a is the fourth thin film transistor T14 of the thin film transistor substrate 800 and the first-second Q discharge transistor T3_b is the third thin film transistor T13 of the thin film transistor substrate 800, the respective planar areas of the third channel portion 231n and the fourth channel portion 232n are made equal in a plane so that PBTS degradation can be applied evenly to the first-first Q discharge transistor T3_a and the first-second Q discharge transistor T3_b.

The second charging circuit 30 can charge the QB node with the high potential voltage VDD in response to the high potential voltage VDD applied to the first power terminal 4. Specifically, the second charging circuit 30 can include QB charging transistors T4_a, T4_b that charge the QB node with the high potential voltage VDD. For example, the second charging circuit 30 can include a first QB charging transistor T4_a having a gate electrode and a drain electrode connected to the first power terminal 4 and a source electrode connected to a drain electrode of the second QB charging transistor T4_b. For example, the drain electrode of the first QB charging transistor T4_a is applied with the high potential voltage VDD. Additionally, the second charging circuit 30 may include the second QB charging transistor T4_b having a gate electrode connected to the first power terminal 4, a drain electrode connected to the source electrode of the first QB charging transistor T4_a, and a source electrode connected to the QB node.

According to an example embodiment of the present disclosure, the QB charging transistors T4_a, T4_b may include any of the thin film transistor substrates 100, 200, 300, 400, 500, 600, 700 illustrated in FIGS. 1 to 6C. For example, the first QB charging transistor T4_a may be the second thin film transistor T12 of any of the thin film transistor substrates 100, 200, 300, 400, 500, 600, 700, and the second QB charging transistor T4_b may be the first thin film transistor T11 of any of the thin film transistor substrates 100, 200, 300, 400, 500, 600, 700.

In an example embodiment where the first QB charging transistor T4_a is the second thin film transistor T12 of the thin film transistor substrate 100, 200, 300, 400, 500, 600, or 700, and the second QB charging transistor T4_b is the first thin film transistor T11 of the thin film transistor substrate 100, 200, 300, 400, 500, 600, or 700, it is possible to prevent or suppress deterioration in the first QB charging transistor T4_a to which a high potential voltage (e.g., VDD) is applied.

The second discharge circuit 40 can discharge the QB node to the gate-off voltage VSS of the second power terminal 8 in response to the control of the Q node. The second discharge circuit 40 can discharge the QB node to the gate-off voltage VSS of the second power terminal 8 in response to the control of the set terminal 2 to which the start signal VST or the output CRn−4 of the preceding stage is supplied. The output CRn−4 of the preceding stage can be the gate output OUTn−4 output from the (n−4)th preceding stage.

The second discharge circuit 40 may include a first QB discharge transistor T5q having a gate electrode connected to the Q node, a source electrode connected to the second power terminal 8, and a drain electrode connected to the QB node. The second discharge circuit 40 may further include a second QB discharge transistor T5c having a gate electrode connected to the set terminal 2, a source electrode connected to the second power terminal 8, and a drain electrode connected to the QB node.

The output circuit 50 includes a pull-up transistor T6 that is pulled up by the control of the Q node and outputs a clock signal CLKn applied to the first clock terminal 12 as a gate output OUTn through the output terminal 14. The output circuit 50 additionally includes a pull-down transistor T7 that is pulled down by the control of the QB node opposite to the Q node and outputs a gate-off voltage VSS from the second power terminal 8 as a gate output OUTn through the output terminal 14. The pull-up transistor T6 may have a gate electrode connected to the Q node, a source electrode connected to the output terminal 14, and a drain electrode connected to the first clock terminal 12. For example, the pull-up transistor T6 may be turned on during the on period of the Q node and output a clock signal CLKn from the first clock terminal 12 as a scan signal of the gate output OUTn through the output terminal 14. For example, the pull-up transistor T6 can be pulled up by the control of the Q node to output the clock signal CLKn input through the first clock terminal 12 to the output terminal 14.

The output circuit 50 further includes an output capacitor CB connected between the gate electrode (the Q node) and the source electrode (the output terminal 14) of the pull-up transistor T6.

The pull-down transistor T7 may have a gate electrode connected to the QB node, a source electrode connected to the second power terminal 8, and a drain electrode connected to the output terminal 14. For example, the pull-down transistor T7 may be turned on during the on period of the QB node corresponding to the off period of the Q node and may output the gate off voltage VSS from the second power terminal 8 as the off voltage of the gate output OUTn through the output terminal 14. For example, the pull-down transistor T7 may pull-down the output terminal 14 by control of the QB node.

The QB stabilization circuit 60 can stably discharge the QB node to the gate-off voltage VSS during the on-period of the Q node in response to the inverted clock signal CLK_B applied through the second clock terminal 5 and the output CRn−2 of the (n−2)th preceding stage applied through the control terminal 7.

The QB stabilization circuit 60 may include two transistors T8, T9 and two capacitors C1, C2. The QB stabilization circuit 60 may include a first capacitor C1 connected between the second clock terminal 5 and a connection node A to transmit an inverted clock signal CLK_B to the connection node A, and include a second capacitor C2 connected between a control terminal 7 and the connection node A to transmit an output CRn−2 of the (n−2)th preceding stage to the connection node A.

The QB stabilization circuit 60 may include a third QB discharge transistor T9 that is controlled by the connection node A to discharge the QB node to the gate-off voltage VSS of the second power terminal 8 and include an initialization transistor T8 that is controlled by the stabilization signal (STB) applied to the stabilization terminal 18 to initialize the connection node A to the gate-off voltage VSS of the second power terminal 8. The third QB discharge transistor T9 may have a gate electrode connected to the connection node A, a source electrode connected to the second power terminal 8, and a drain electrode connected to the QB node. The initialization transistor T8 may have a gate electrode connected to the stabilization terminal 18, a source electrode connected to the second power terminal 8, and a drain electrode connected to the connection node A.

The circuit diagram of FIG. 10 is an example equivalent circuit diagram for an example pixel P of a display apparatus 1000 including an organic light-emitting diode (OLED) as a display element 710.

As illustrate in FIG. 10, an example pixel P includes a display element 710 and a pixel driving circuit PDC that drives the display element 710. Specifically, a display apparatus 1000 according to an example embodiment of the present disclosure may include a pixel driving circuit PDC on a base substrate 110.

The example pixel driving circuit PDC of FIG. 10 includes a first thin film transistor TR1 which is a switching transistor and a second thin film transistor TR2 which is a driving transistor.

According to an example embodiment of the present disclosure, in a driving transistor, current can flow in one direction, and in a switching transistor, current can flow in both directions. According to another example embodiment of the present disclosure, any of the thin film transistor substrates 100, 200, 300, 400, 500, 600, 700 described above can be used as a driving transistor of a pixel driving circuit PDC illustrated in FIG. 10. The thin film transistor substrate 800 described above can be used as a switching transistor of the pixel driving circuit PDC illustrated in FIG. 10. Specifically, in a driving transistor in which current flows in one direction, an asymmetric thin film transistor substrate 100, 200, 300, 400, 500, 600, or 700 can be used, and in a switching transistor in which current flows in both directions, a symmetric thin film transistor substrate 800 can be used.

According to another example embodiment of the present disclosure, the thin film transistor 100, 200, 300, or 400 described above can be used as a driving transistor of the pixel driving circuit PDC illustrated in FIG. 10.

According to embodiments of the present disclosure, the following advantageous effects may be obtained.

A thin film transistor substrate according to one or more embodiments of the present disclosure can reduce stress applied to a thin film transistor due to high drain bias by forming a large channel area of a thin film transistor to which a high potential voltage is applied.

A thin film transistor substrate according to one or more embodiments of the present disclosure can reduce stress applied to a thin film transistor due to high drain bias by allowing a drain electrode of a thin film transistor to which a high potential voltage is applied to have a larger planar area than a source electrode in a plane.

A thin film transistor substrate according to one or more embodiments of the present disclosure can implement a narrower bezel by integrating a drain electrode and a source electrode of two different thin film transistors into a shared circular, oval, or elliptical structure.

In addition to the effects mentioned above, other features and advantages of the present disclosure are described above or may be clearly understood from such description and explanation by those skilled in the art to which the present disclosure pertains.

It will be apparent to those skilled in the art that the present disclosure is not limited by the above-described example embodiments and the accompanying drawings and that various substitutions, modifications, and variations can be made in the present disclosure without departing from the spirit or scope of the disclosures. Consequently, the protected scope of the present disclosure may be defined by the accompanying claims and their equivalents, and it is intended that all variations or modifications derived from the meaning, scope, and equivalent concept of the claims and their equivalents fall within the scope of the present disclosure.

What is claimed is:

1. A thin film transistor substrate, comprising:
a base substrate; and
a first thin film transistor and a second thin film transistor on the base substrate and connected to each other in series,
wherein the first thin film transistor includes:
a first active layer having a first channel portion;
a first gate electrode insulated from the first active layer and overlapping the first active layer; and
a first source electrode and a first drain electrode in contact with the first active layer and spaced apart from each other,
wherein the second thin film transistor includes:
a second active layer having a second channel portion;
a second gate electrode insulated from the second active layer and overlapping the second active layer; and
a second source electrode and a second drain electrode in contact with the second active layer and spaced apart from each other, and
wherein the first drain electrode and the second source electrode are formed integrally and disposed on a same underlying layer.

2. The thin film transistor substrate of claim 1, wherein the integrally formed first drain electrode and second source electrode together have a circular, rounded, oval, or elliptical shape in a plan view.

3. The thin film transistor substrate of claim 1, wherein:
the first gate electrode and the second gate electrode integrally form a closed loop shape in a plan view; and
the first drain electrode and the second source electrode are disposed inside of the closed loop shape integrally formed by the first gate electrode and the second gate electrode in the plan view.

4. The thin film transistor substrate of claim 1, wherein:
the first active layer further includes:
a first source conductor portion disposed at one side of the first channel portion; and
a first drain conductor portion disposed at the other side of the first channel portion;
the second active layer further includes:
a second source conductor portion disposed at one side of the second channel portion; and
a second drain conductor portion disposed at the other side of the second channel portion; and
the first channel portion and the second channel portion are separated from each other by an opening portion therebetween.

5. The thin film transistor substrate of claim 1, wherein:
the first channel portion has a first length and has a first width perpendicular to the first length and extending along the first channel portion;
the second channel portion has a second length and has a second width perpendicular to the second length and extending along the second channel portion;
the second width is longer than the first width; and
the first length and the second length are equal.

6. The thin film transistor substrate of claim 1, wherein the second channel portion has a larger planar area than the first channel portion in a plan view.

7. The thin film transistor substrate of claim 1, wherein the second drain electrode has a larger planar area than the first source electrode in a plan view, and the first source electrode has a larger planar area than the first drain electrode in the plan view.

8. The thin film transistor substrate of claim 1, wherein:
the first channel portion has a U shape in a plan view, and the second channel portion has an inverted U shape in the plan view; and
the first gate electrode has a U shape in the plan view, and the second gate electrode has an inverted U shape in the plan view.

9. The thin film transistor substrate of claim 1, wherein the first source electrode has a U shape in a plan view, and the second drain electrode has an inverted U shape in the plan view.

10. The thin film transistor substrate of claim 1, wherein:
the first gate electrode and the second gate electrode integrally form any one of a circular ring, an elliptical ring, and a rectangular ring with rounded corners in a plan view; and
each of an inner surface of the first source electrode and an inner surface of the second drain electrode has a round or curved shape in the plan view.

11. The thin film transistor substrate of claim 1, wherein:
the first source electrode, the first drain electrode, the second source electrode, and the second drain electrode are disposed on the same underlying layer, that is different from a layer on which the first gate electrode and the second gate electrode are disposed; and
the first active layer is disposed between the base substrate and the first gate electrode, and the second active layer is disposed between the base substrate and the second gate electrode.

12. The thin film transistor substrate of claim 11, wherein:
the first thin film transistor includes a first light-blocking layer electrically connected to the first gate electrode and disposed between the base substrate and the first active layer;
the second thin film transistor includes a second light-blocking layer electrically connected to the second gate electrode and disposed between the base substrate and the second active layer;
the first light-blocking layer overlaps the first gate electrode; and
the second light-blocking layer overlaps the second gate electrode.

13. The thin film transistor substrate of claim 1, wherein:
the first gate electrode is disposed between the base substrate and the first active layer; and
the second gate electrode is disposed between the base substrate and the second active layer.

14. A display apparatus comprising the thin film transistor substrate of claim 1.

15. The display apparatus of claim 14, further comprising:
a plurality of pixels each having a pixel driving circuit;
a plurality of gate lines connected respectively to the plurality of pixels; and
a gate driver having a plurality of stages each configured to drive a corresponding one of the plurality of gate lines and the pixel driving circuit of the corresponding one of the plurality of pixels,
wherein each of the plurality of stages includes:
an output circuit including a pull-up transistor configured to be pulled up by control of a Q node and to output a first clock signal input through a first clock terminal as an output to an output terminal, and including a pull-down transistor configured to pull down the output terminal by control of a QB node; and
a control circuit configured to charge and discharges the Q node and to charge and discharge the QB node opposite to the Q node,
wherein the control circuit includes QB charging transistors configured to charge the QB node with a high potential voltage,
wherein the QB charging transistors include a first QB charging transistor and a second QB charging transistor,
wherein a drain electrode of the first QB charging transistor is configured to receive the high potential voltage, and a source electrode of the second QB charging transistor is connected to the QB node, and
wherein the first QB charging transistor is the second thin film transistor, and the second QB charging transistor is the first thin film transistor.

16. The display apparatus of claim 15, wherein:
the control circuit further includes Q discharge transistors configured to discharge the Q node to a gate-off voltage by control of the QB node;
the Q discharge transistors include a third thin film transistor and a fourth thin film transistor connected in series with each other;
the third thin film transistor includes:
a third active layer having a third channel portion;
a third gate electrode insulated from the third active layer and overlapping the third active layer; and
a third source electrode and a third drain electrode in contact with the third active layer and spaced apart from each other;
the fourth thin film transistor includes:
a fourth active layer having a fourth channel portion;
a fourth gate electrode insulated from the fourth active layer and overlapping the fourth active layer; and
a fourth source electrode and a fourth drain electrode in contact with the fourth active layer and spaced apart from each other;
the third gate electrode and the fourth gate electrode are formed integrally and are disposed on the same underlying layer; and
the third drain electrode and the fourth source electrode are formed integrally, and a planar area of the third channel portion is equal to a planar area of the fourth channel portion in a plan view.

17. A thin film transistor substrate, comprising:
a base substrate; and
a first thin film transistor and a second thin film transistor on the base substrate and connected to each other in series,
wherein the first thin film transistor and the second thin film transistor share an integrated gate electrode having a closed loop shape in a plan view, the integrated gate electrode including a first gate electrode at one portion of the closed loop shape and a second gate electrode at another portion of the closed loop shape,
wherein the first thin film transistor includes:
a first active layer having a first channel portion;
the first gate electrode insulated from the first channel portion and overlapping the first channel portion; and
a first source electrode and a first drain electrode in contact with the first active layer and disposed respectively at opposite sides of the first channel portion, and
wherein the second thin film transistor includes:
a second active layer having a second channel portion;
the second gate electrode insulated from the second channel portion and overlapping the second channel portion; and
a second source electrode and a second drain electrode in contact with the second active layer and disposed respectively at opposite sides of the second channel portion.

18. The thin film transistor substrate of claim 17, wherein:
the first drain electrode and the second source electrode are formed integrally and disposed on a same underlying layer; and
the integrally formed first drain electrode and second source electrode together have a circular, rounded, oval, or elliptical shape in the plan view.

19. The thin film transistor substrate of claim 17, wherein:
the integrated gate electrode further includes at least one connection portion connected between the first gate electrode and the second gate electrode; and
the first gate electrode, the second gate electrode, and the at least one connection portion together integrally form the closed loop shape of the integrated gate electrode.

20. The thin film transistor substrate of claim 19, wherein:
the first channel portion of the first active layer and the second channel portion of the second active layer are separated from each other by at least one opening portion; and
the at least one connection portion of the integrated gate electrode overlap the at least one opening portion in the plan view.

21. The thin film transistor substrate of claim 17, wherein:
the first channel portion has a U shape, and the second channel portion has an inverted U shape in the plan view; and
the first gate electrode has a U shape, and the second gate electrode has an inverted U shape in a plan view.

22. The thin film transistor substrate of claim 17, wherein the closed loop shape of the integrated gate electrode is a shape of a circular ring, an oval ring, an elliptical ring, or a rectangular ring with rounded corners in the plan view.

23. The thin film transistor substrate of claim 17, wherein the second channel portion has a larger planar area than the first channel portion in the plan view.
